(19) United States
(12) Patent Application Publication
(10) Pub. No.: US 2005/0136858 A1
(43) Pub. Date: Jun. 23, 2005

(54) Bipolar modulator

(76) Inventor: Eliav Zipper, Tel Aviv (IL)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/742,893

(22) Filed: Dec. 23, 2003

(51) Int. Cl. H04B 1/02; H04B 1/66; H03C 1/52

(52) U.S. Cl. 455/102

(57) ABSTRACT

Embodiments of the invention describe a transmitter to synthesize an output signal by combining a bi-polar base band amplitude signal with a phase-modulated signal. The bi-polar base band amplitude may have either positive or negative values depending on at least one predetermined criterion related to an input signal of the transmitter.

### BACKGROUND OF THE INVENTION

In a communication system, In-phase and Quadrature components of a base-band signal may be modulated onto a carrier wave using a modulator, and the modulated signal may be up-converted using one or more frequency mixers. The carrier wave includes the amplitude and phase components of the modulating signal. Amplification between the modulator and an antenna is necessary. This amplification should be as linear and efficient as possible. Non-linear amplification creates distortion that may cause, among other things, error in the information vector. In some cases, this error may cause broadening of the frequency spectrum of the transmitted signal. Such broadening may interfere with nearby channels and may reduce traffic capacity. Broadened frequency spectrum may also result in undesirable consumption of power, thus reducing the efficiency of the transmitter.

In a conventional polar-loop transmitter, an information signal is split into its polar components, which consist of a phase component and an amplitude component. The two components are processed in separate paths and are subsequently recombined to produce an output signal. One problem associated with conventional polar-loop transmitters is that modern communication techniques introduce modulation schemes, for example, Code Division Multiple Access (CDMA) and Wideband CDMA schemes, where the instant signal trajectory may cross the origin on the phasor diagram. This zero-crossing trajectory creates several difficulties for conventional polar-loop transmitters. For example, a zero-crossing trajectory may have a phase component discontinuity similar to a step-function that results from the instantaneous transition of the phase by 180 degrees. The amplitude component at this zero-crossing occurrence may also contain a time derivative discontinuity. These mathematical discontinuities, which may also be present in higher derivatives of the components; may be filtered out if a limited bandwidth is used for transmission. In order to avoid Adjacent Channel Leakage Power Ratio (ACLR) degradation and increased Error Vector Magnitude (EVM) conventional polar modulation scheme may require a wider bandwidth.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features and advantages thereof, may best be understood by reference to the following detailed description when read with the accompanied drawings in which:

FIG. 1 is a schematic illustration of a wireless communication system that may use a transmitter according to an exemplary embodiment of the present invention;

FIG. 2 is schematic illustration of an I-Q trajectory of a zero-crossing complex signal.

FIG. 3 is a schematic illustration of a polar representation of the complex signal of FIG. 2 in terms of phase and amplitude as a function of time;

FIG. 4 is a schematic illustration of a bi-polar representation of the complex signal of FIG. 2, in accordance with exemplary embodiments of the invention, in terms of phase and amplitude as a function of time;

FIG. 5 is a schematic illustration of a simulated signal constellation of a transmission signal generated by a limited bandwidth polar modulator;

FIG. 6 is a schematic diagram of a simulated signal constellation of a transmission signal generated by a limited bandwidth bi-polar modulator in accordance with exemplary embodiments of the invention;

FIG. 7 is a functional block diagram of a transmitter in accordance with an exemplary embodiment of the present invention

FIG. 8 is a functional block diagram of a signal recombining unit in accordance with an exemplary embodiment of the present invention;

FIG. 9 is a flow chart of a method of generating a modulated output signal in accordance with an exemplary embodiment of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF EMBODIMENTS OF THE INVENTION

In the following detailed description, numerous specific details are set forth in order to provide a thorough understanding of the invention. However, it will be understood by those of ordinary skill in the art that the invention may be practiced without these specific details. In other instances, well-known methods, procedures, components, units and/or circuits have not been described in detail so as not to obscure the invention.

It should be understood that embodiments of the invention may be used in a variety of applications. Although the invention is not limited in this respect, embodiments of the invention may be used in many apparatuses, for example, a transmitter, a receiver, a transceiver, a transmitter-receiver, and/or a wireless communication device. Wireless communication devices intended to be included within the scope of the invention include, by way of example only, cellular radio-telephone communication systems, cellular telephones, wireless telephones, cordless telephones, Wireless Local Area Networks (WLAN) and/or devices operating in accordance with the existing IEEE 802.11a, 802.11b, 802.1 μg, 802.11n and/or future versions of the above standards, Personal Area Networks (PAN), Wireless PAN (WPAN), units and/or devices which are part of the above WLAN and/or PAN and/or WPAN networks, one way and/or two-way radio communication systems, one-way pagers, two-way pagers, Personal Communication Systems (PCS) devices, a Portable Digital Assistant (PDA) device which incorporates a wireless communications device, Ultra Wide Band (UWB) devices, OFDM WLAN, and the like.

By way of example, types of cellular communication systems intended to be within the scope of the invention include, although not limited to, Direct Sequence-Code Division Multiple Access (DS-CDMA) cellular radio-telephone communication systems, Global System for Mobile Communications (GSM) cellular radio-telephone systems, North American Digital Cellular (NADC) cellular radio-telephone systems, Time Division Multiple Access (TDMA) systems, Extended-TDMA (E-TDMA) cellular radio-telephone systems, Wideband CDMA (WCDMA) systems, General Packet Radio Service (GPRS) systems, 3G systems, 3.5G systems, 4G systems, communication devices using various frequencies and/or range of frequencies for reception and/or transmission, communication devices using 2.4 Gigahertz frequency, communication devices using 5.2 Gigahertz frequency, communication devices using 24 Gigahertz frequency, communication devices using an Industrial Scientific Medical (ISM) band and/or several ISM bands, and other existing and/or future versions of the above.

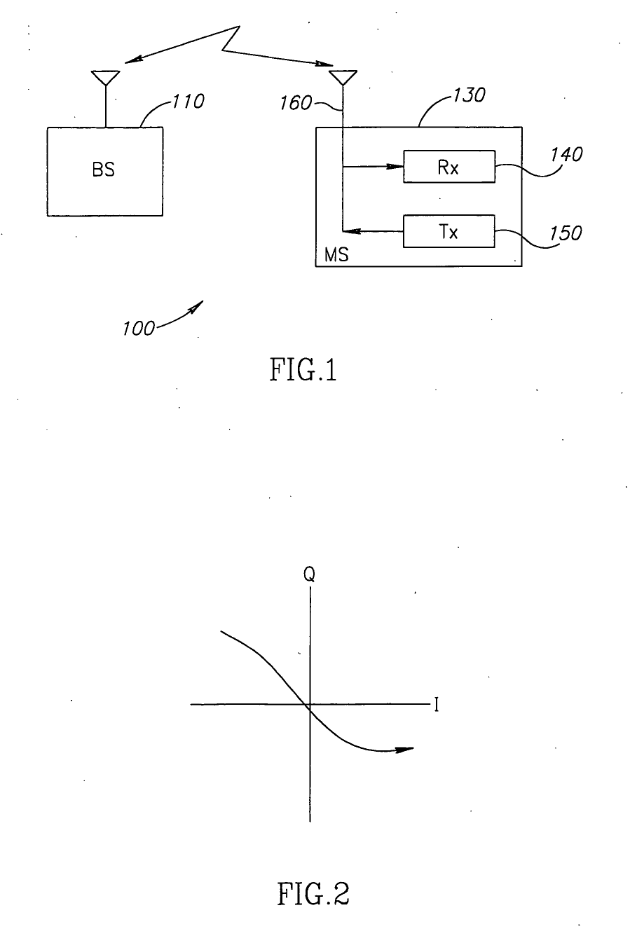

Turning to FIG. 1, a wireless communication system 100, for example, a cellular communication system, in accordance with exemplary embodiments of the invention, is shown. Although the scope of the present invention is not limited in this respect, the exemplary cellular communication system 100 may include at least one base station (BS) 110 and at least one mobile station (MS) 130. Mobile station 130 may include a receiver 140, a transmitter 150, and an antenna 160; for example, an omni-directional antenna, a highly-directional antenna, a steerable antenna, a dipole antenna, an internal antenna, and the like.

In some embodiments of the present invention, transmitter 150 may include a universal transmitter architecture to support digital data transmission. Although the scope of the present invention is not limited in this respect, the universal transmitter architecture may include a base-band processor to generate separate bi-polar amplitude and phase signals, and a mixer, which may include any type of mixer or multiplier, e.g., as are known in the art, and/or any other suitable unit, circuit or logic, to recombine the bi-polar amplitude and phase signals into a recombined output signal. In other embodiments of this invention, the transmitter may also include a modulator to modulate the phase signal.

It will be appreciated that the term “bi-polar” as used herein refers to a non-conventional polar representation of a complex signal in accordance with embodiments of the present invention, as described below. According to embodiments of the invention, the described process of generating separate bi-polar amplitude and phase signals refers to a process whereby a complex signal may be separated into separate amplitude and phase signals, and the sign of the amplitude signal may have both positive and negative values. The sign of the amplitude signal according to embodiments of the invention may be controlled by at least one pre-determined criterion. This is in contrast to conventional polar representations, in which a separated amplitude signal has only positive values. The difference between polar and bi-polar representations is demonstrated below with reference to the diagrams of FIGS. 2,3 and 4:

FIG. 2 illustrates the I-Q plane of a signal to be transmitted. A region of interest to embodiments of the present invention is close to the origin of the I-Q plane, e.g., where the signal crosses zero or passes near zero. In this region the translation from I-Q coordinates to polar coordinates is problematic because the phase, at zero, is not uniquely defined.

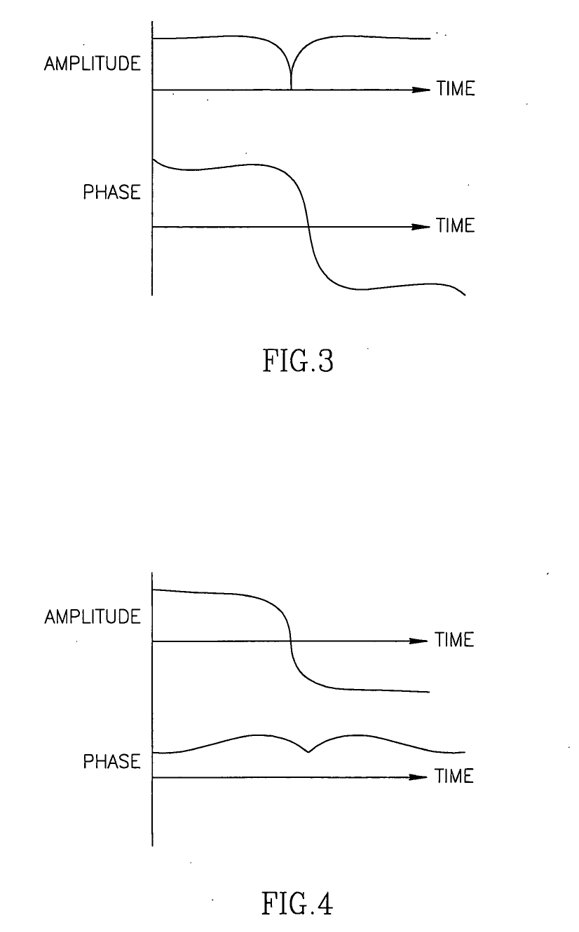

FIG. 3 shows how a zero-crossing signal may be represented in a conventional polar representation of phase and amplitude. When crossing zero, the phase of the signal appears as a step-function and the amplitude has a sharp discontinuity. Due to these characteristics, a large bandwidth may be required in order to preserve all the content of the signal when carried over into the modulation stage of an RF transmitter. In a limited bandwidth device, some of this content may be filtered out and may result in degradation of output signal and device functionality, as may be reflected, for example, in degraded ACLR and EVM.

In FIG. 4, the representation of a zero-crossing signal in a bi-polar representation according to embodiments of the invention is shown. As can be seen in FIG. 4, by allowing the bi-polar amplitude to take on both positive and negative values, the amplitude at the zero-crossing does not have the shape of an abrupt impulse, but rather a smooth step-like function, and therefore may have fewer high-frequency components. Additionally, the phase component at the zero-crossing may be characterized by a significantly smoother function

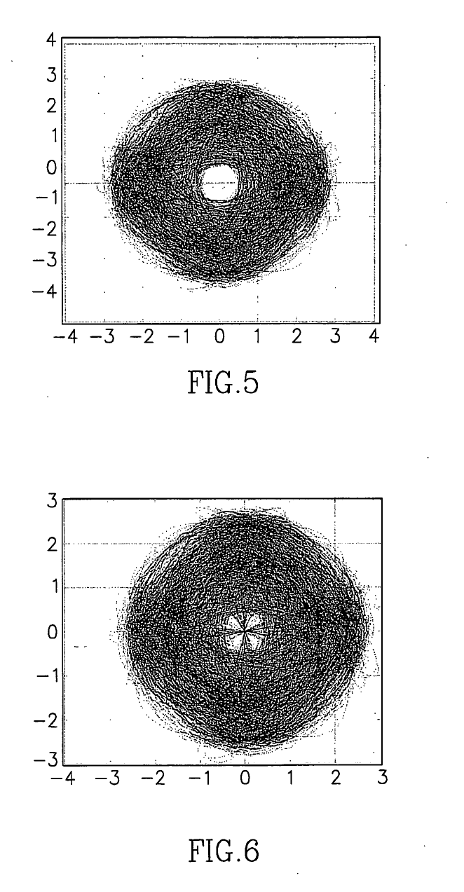

The benefits of reducing these mathematical discontinuities can be demonstrated with reference to FIGS. 5 and 6.

FIG. 5 schematically illustrates a signal constellation resulting from a simulation of a limited bandwidth polar modulation of a base band transmission signal. The signal being simulated may be a spread spectrum signal, wideband signal, or a wideband spread spectrum signal. A limited bandwidth modulation may cutoff the high frequency components associated with the mathematical singularities generated at the zero-crossing. This cutoff may lead to zero avoidance as is indicated by the “hole” at the center of the constellation. Zero avoidance may result in performance degradation due to ACLR.

FIG. 6 schematically illustrates a signal constellation of a base band transmission signal having a bandwidth as in FIG. 5, but where the modulation is simulated based on a bi-polar modulator in accordance with embodiments of the present invention. As can been seen from comparing the diagrams in FIGS. 5 and 6, the bi-polar presentation preserves significantly more of the trajectory for transmission, at the same limited bandwidth.

The present invention may require two stages to implement the bi-polar modulation of complex signals: a stage involving, for example, a Base-Band (BB) processor to generate BB bi-polar amplitude and phase signals from an input signal; and a radio frequency (RF) stage to recombine the modulated output signals for transmission.

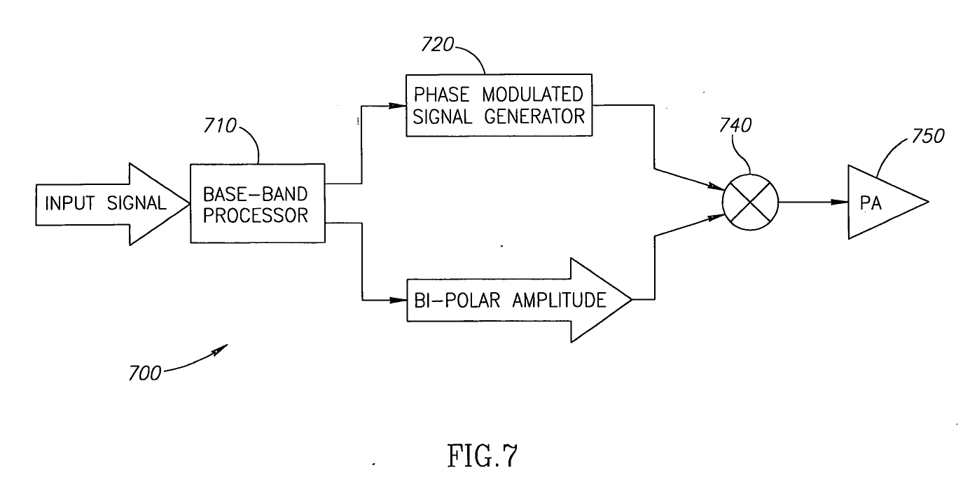

FIG. 7 is a functional block diagram of a transmitter in accordance with exemplary embodiments of the present invention. Transmitter 700 may receive a complex input signal from a signal source (not shown). Although the scope of the present invention is not limited in this respect, the transmitter may include a BB processor 710, which may include any suitable software or hardware or any suitable combination of software and/or hardware to process the input signal and generate the phase and bi-polar amplitude signals based on the input signal, as described herein. The phase signal may be used by signal generator 720 to generate a phase-modulated signal. Although the scope of the present invention is not limited in this respect, the transmitter may include a mixer 740 to recombine the phase modulated signal from generator 720 with the bi-polar BB amplitude signal provided by BB processor 710. Mixer 740 may include any suitable type of combining unit, e.g., a multiplier, or a recombining circuit or logic, as are know in the art, to recombine the phase and amplitude signals into a recombined signal. The modulated, recombined signal from mixer 740 may be amplified by a power amplifier 750 to provide an amplified signal suitable for RF transmission.

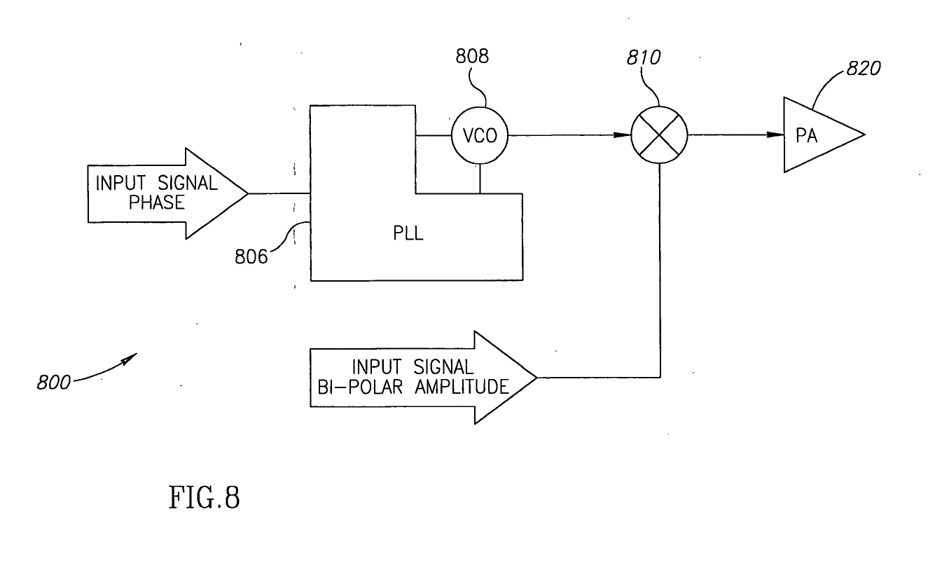

FIG. 8 is a functional block diagram of an exemplary embodiment of a recombining circuit in accordance with an embodiment of the present invention. The recombining circuit 800 may receive a bi-polar modulated input signal from a signal source (not shown in the drawings). The bi-polar modulated signal may include a phase modulated signal and a baseband bi-polar amplitude. The phase modulated signal may be input to a Phase Loclced Loop (PLL) 806 and a mixer 810 may combine the output from the PLL with the base bi-polar amplitude. The output of mixer 810 may be amplified by a power amplifier 820 and transmitted via an antenna as described above. The mixer 810 may include any type of multiplier or combining circuit or logic as are known in the art.

Transmitter 700 may help reduce or even eliminate the difficulties associated with zero-crossings of a signal, e.g., the difficulties that exist in conventional polar-loop transmitters, by reducing the discontinuities in phase and amplitude associated with the zero-crossings, as described above with reference to FIG. 2 through 6.

A BB processor, e.g., BB processor 710 of FIG. 7, which may or may not be a digital processor, may generate the bi-polar amplitude and phase signals to be modulated and transmitted. This may be done either by logic, circuit or any suitable combination of the two, by any suitable method known in the art.

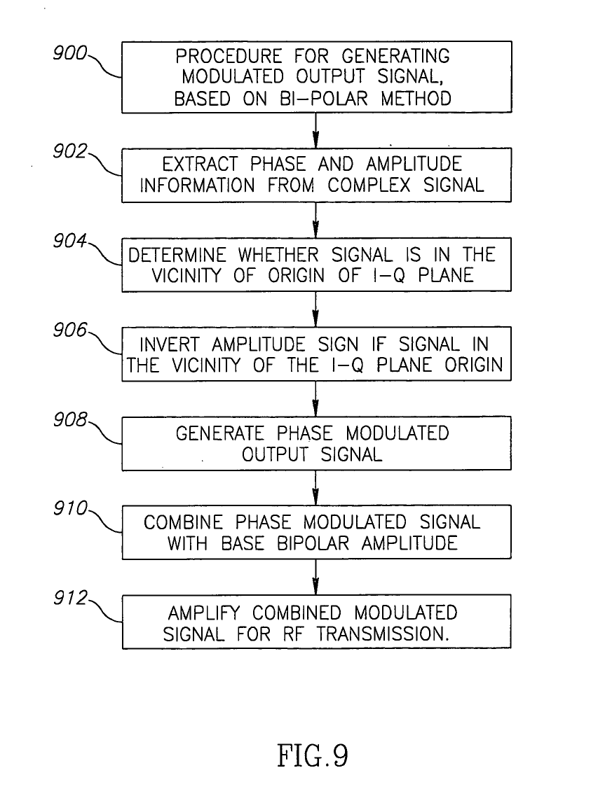

FIG. 9 is a flow chart for a method of controlling the sign of a bi-polar base band signal and generating a modulated output signal in accordance with an exemplary embodiment of the present invention. Although the method described in FIG. 9 specifies a set of operations, the present invention is not limited in this respect and can be embodied in other, similar in intent, operations. Although the individual operations of the procedure are illustrated and described as separate operations, it should be noted that one or more of the individual operations may be performed concurrently. Further, the operations are not necessarily performed in the order illustrated. Transmitter 700 (FIG. 7) is an example of a modulator suitable for use when performing this procedure; however other configurations may also be suitable.

In block 902, phase and amplitude information are extracted from a complex input signal. Block 904 determines whether the signal is sufficiently close to the I-Q plane origin, in order to determine whether the signal is zero crossing. Although not limited in this respect, an exemplary implementation of block 904 may include the generation of an interpolated curve segment, for example, a generally straight-line interpolation, between two sampled points on the signal trajectory, and determining whether the value of the distance between any point on this interpolated segment and the origin is less than, for example, a predetermined percentage, for example, between 0 and 20 percent, e.g., 10 percent, of the maximum absolute value of the signal amplitude of any points on the interpolated curve. It will be appreciated that the exemplary criterion of determining closeness to origin based on a predetermined percentage of the maximum signal amplitude is given for demonstrative purposes only. Any other suitable criteria for comparing signals may be used, in alternative embodiments of the invention, to determine whether a signal should be identified as zero crossing.

In block 906, the bi-polar amplitude sign is controlled, e.g. in this example inverted, if the signal is determined to be zero-crossing in block 904. Each zero crossing event may invert the amplitude sign of the signal, while the phase of the signal may be derived from the input signal and, depending on the sign of the bi-polar amplitude; phase inversion may be avoided at zero-crossing events. The bi-polar amplitude remains of the same sign as long as the signal is not sufficiently close to the origin of the I-Q plane. The vicinity of the I-Q plane origin that will be considered as indicative of a zero crossing signal may be determined per modulation scheme and/or detailed operation scheme. In block 908 the input signal phase information is passed to a phase modulator that generates a phase modulated signal. In block 910 the phase modulated signal and bi-polar amplitude are recombined in a mixer that may include a multiplier as is known in the art. In block 912 the recombined modulated signal is amplified for RF transmission.

Some embodiments of the invention may be implemented, for example, using a machine-readable medium or article which may store an instruction or a set of instructions that, if executed by a machine (for example, by station 110, and/or by other suitable machines), cause the machine to perform a method and/or operations in accordance with embodiments of the invention. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, various types of Digital Versatile Disks (DVDs), a tape, a cassette, or the like. The instructions may include any suitable type of code, for example, source code, compiled code, interpreted code, executable code, static code, dynamic code, or the like, and may be implemented using any suitable high-level, low-level, object-oriented, visual, compiled and/or interpreted programming language, e.g., C, C++, Java, BASIC, Pascal, Fortran, Cobol, assembly language, machine code, or the like

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. An apparatus comprising:
a transmitter able to control a sign of a bi-polar base band amplitude signal based on at least one predetermined criterion related to an input signal of the transmitter.

2. An apparatus according to claim 1 wherein
said transmitter is able to generate an output signal by combining said bi-polar base band amplitude signal with a phase modulated signal.

3. An apparatus according to claim 2 wherein said transmitter comprises:
a base-band processor able to provide said bi-polar base band signal.

4. An apparatus according to claim 3, wherein said base band processor is able to determine whether said input signal approaches a zero-crossing, and to invert the sign of said bi-polar amplitude signal if said input signal approaches a zero-crossing.

5. An apparatus according to claim 4 wherein said base band processor is able to determine whether said input signal is within a domain proximal to the origin of a predefined complex plane.

6. An apparatus according to claim 5 wherein said base band processor is able to determine whether a distance between a value related to said input signal is closer to said origin than a predetermined fraction of a maximal signal amplitude.

7. An apparatus according to claim 3 wherein said transmitter further comprises:
a modulator operably coupled to said base band processor to generate said phase modulated signal.

8. An apparatus according to claim 2 wherein said transmitter further comprises:
a mixer to combine said bi-polar base-band signal with said phase modulated signal.

9. The apparatus of claim 8 wherein said transmitter further comprises:
a power amplifier operably coupled to the output of said mixer to amplify said combined signal.

10. A method comprising:
controlling a sign of a bi-polar base band amplitude signal based on at least one predetermined criterion related to a transmission input signal.

11. The method of claim 10 further comprising
generating an output signal by combining said bi-polar base-band amplitude signal with a phase modulated signal.

12. The method according to claim 10, wherein controlling a sign comprises:
determining whether said input signal approaches a zero-crossing; and
inverting the sign of said bi-polar amplitude signal if said input signal approaches a zero-crossing.

13. The method according to claim 12 wherein determining whether said input signal approaches a zero-crossing comprises:
determining whether said input signal is within a domain proximal to the origin of a predefined complex plane.

14. The method according to claim 13 wherein determining whether said input signal is within a domain proximal to the origin of a predefined complex plane comprises:
determining whether a distance between a value related to said input signal is closer to said origin than a predetermined fraction of a maximal signal amplitude.

15. A wireless communication device comprising:
a transmitter able to control a sign of a bi-polar base band amplitude signal based on at least one predetermined criterion, to generate an output signal;
an internal antenna to transmit said output signal.

16. A wireless communication device according to claim 15 wherein said transmitter is able to generate said output signal by combining said bi-polar base band amplitude signal with a phase modulated signal.

17. A wireless communication device according to claim 15, wherein said transmitter comprises:
a base-band processor able to provide said bi-polar base band amplitude signal.

18. A wireless communication device according to claim 17, wherein said base band processor is able to determine whether said input signal approaches a zero-crossing, and to invert the sign of said bi-polar amplitude signal if said input signal approaches a zero-crossing.

19. A wireless communication device according to claim 18 wherein said base band processor is able to determine whether said input signal is within a domain proximal to the origin of a predefined complex plane.

20. A wireless communication device according to claim 19 wherein said base band processor is able to determine whether a distance between a value related to said input signal is closer to said origin than a predetermined fraction of a maximal signal amplitude.

21. A wireless communication device according to claim 16 wherein said transmitter further comprises:
a mixer to combine said bi-polar signal with said phase modulated signal.

22. A wireless communication system comprising:
at least two communication stations wherein at least one communication station of the at least two communication stations comprises a transmitter able to control a sign of a bi-polar base band amplitude signal based on at least one predetermined criterion, to generate an output signal.

23. A wireless communication system according to claim 22 wherein said transmitter is able to generate said output signal by combining said bi-polar base band amplitude signal with a phase modulated signal.

24. A wireless communication system according to claim 22 wherein said transmitter comprises:
a base-band processor to provide said bi-polar base band amplitude signal.

25. A wireless communication system according to claim 23 wherein said transmitter further comprises:
a mixer to combine said bi-polar signal with said phase modulated signal;

26. An article comprising: a storage medium, having stored thereon instructions that, when executed by a computing platform, result in:
controlling a sign of a bi-polar base band amplitude signal based on at least one predetermined criterion related to a transmission input signal.

27. The article of claim 26, wherein the instructions further result in:
generating an output signal by combining said bi-polar base-band amplitude signal with a phase modulated signal.

28. The article of claim 26, wherein the instructions that result in controlling a sign, result in:
determining whether said input signal approaches a zero-crossing; and
inverting the sign of said bi-polar amplitude signal if said input signal approaches a zero-crossing.

29. The article of claim 28, wherein the instructions that result in determining whether said input signal approaches a zero-crossing result in:
determining whether said input signal is within a domain proximal to the origin of a predefined complex plane.

30. The article of claim 29, wherein the instructions that result in determining whether said input signal is within a domain proximal to the origin of a predefined complex plane, result in:
determining whether a distance between a value related to said input signal is closer to said origin than a predetermined fraction of a maximal signal amplitude.
